(19) United States
(12) Patent Application Publication
(10) Pub. No.: US 2023/0197891 A1
(43) Pub. Date: Jun. 22, 2023

(54) LED DISPLAY AND PRODUCTION METHOD THEREFOR

(71) Applicant: TOYODA GOSEI CO., LTD., Kiyosu-shi (JP)

(72) Inventor: Koichi GOSHONOO, Kiyosu-shi (JP)

(21) Appl. No.: 18/083,948

(22) Filed: Dec. 19, 2022

(30) Foreign Application Priority Data
Dec. 20, 2021 (JP) 2021-206557
Dec. 20, 2021 (JP) 2021-206559

(51) Int. Cl. H01L 33/08; H01L 33/38; G09G 3/32; H01L 33/00; H01L 27/15

(52) U.S. Cl. CPC H01L 33/08; H01L 33/38; G09G 3/32; H01L 33/005; H01L 27/15; G09G 2310/0264; G09G 2300/0426; G09G 2330/10; H01L 2933/0008

(57) ABSTRACT

The present invention provides a LED display having a simplified driving circuit while preventing defective images. The light-emitting element has a pixel light-emitting part corresponding to one pixel. The pixel light-emitting part has three subpixel light-emitting parts. Each of the subpixel light-emitting parts has a first partial light-emitting part and a second partial light-emitting part connected in parallel. The first partial light-emitting part has a p-electrode. The second partial light-emitting part has a p-electrode. The driving circuit has one transistor for one subpixel light-emitting part. One electrode of the transistor is electrically connected to the first partial light-emitting part through the p-electrode and the second partial light-emitting part through the p-electrode.

### BACKGROUND OF THE INVENTION

### Field of the Invention

The present invention relates to a LED display and production method therefor.

### Background Art

A display device has been used in a variety of fields such as television, desktop computer, notebook computer, and smartphone. A micro-LED display has been researched and developed for image display. A micro-LED display has micro light-emitting elements of approximately 1 μm to 100 μm arranged in a matrix.

In such a micro-LED display, a defective image may be caused by partial light emission failure of a LED element. Patent Document 1 discloses a technique of preventing defective images. In Patent Document 1, two light-emitting diodes are connected in parallel in a LED 300, and the LED 300 has redundancy.

For example, when a short-circuited light-emitting element exists, a current is concentrated in that light-emitting element, and a current may be insufficient in other light-emitting elements. In this case, desired light-emitting elements are difficult to be brightly illuminated. Patent Document 2 discloses a technique of preventing a current from flowing to the light-emitting element having a light emission failure in a large-area light-emitting device (paragraphs [0010]-[0011] of Patent Document 2). For that purpose, the entire light-emitting element is covered with an insulating film 10 (paragraph [0060] and FIG. 2 of Patent Document 2).
Patent Document 1: Japanese Patent Application Laid-Open (kokai) No. 2018-101785
Patent Document 2: Japanese Patent Application Laid-Open (kokai) No. 2006-286991

As described above, in Patent Document 1, two light-emitting diodes of the LED 300 are arranged in parallel. Therefore, a common electrode is required to integrate the electrodes of two light-emitting diodes into one, thereby complicating the structure.

Moreover, the electrode of the micro-LED or the electrode of the driving circuit being bonded to the micro-LED is very small. Therefore, these electrodes are preferably enlarged and simplified as much as possible in terms of mounting accuracy.

Patent Document 2 discloses that a light-emitting device maintaining a desired emission luminance can be manufactured with a high yield even if there is a light-emitting element with low luminous efficiency by accurately selecting a defective light-emitting element and preventing a current from flowing to such a light-emitting element (paragraph [0089] of Patent Document 2).

However, in the display device, when a current is not supplied to a light-emitting part with low luminous efficiency, a defective image may occur due to existence of non-light emitting region. Moreover, the display device has a plurality of light-emitting parts. Therefore, the process is complicated when forming an insulating film for a plurality of light-emitting parts of a large number of light-emitting parts.

### SUMMARY OF THE INVENTION

An object of the present invention is to simplify the structure of the micro-LED and the driving circuit while preventing defective images. Another object of the present invention is to suppress defective images by a simple process.

In a first aspect of the present invention, there is provided a LED display including a monolithic light-emitting element having a plurality of light-emitting parts formed on a substrate, and a driving circuit substrate having a driving circuit for supplying a current to the light-emitting element formed thereon. The light-emitting element has a pixel light-emitting part corresponding to one pixel, the pixel light-emitting part has not less than one subpixel light-emitting part, the subpixel light-emitting part has a first partial light-emitting part and a second partial light-emitting part connected in parallel. The first partial light-emitting part has a first p-electrode, the second partial light-emitting part has a second p-electrode, and the driving circuit has one transistor for the one subpixel light-emitting part. One terminal of the transistor is electrically connected to the first partial light-emitting part through the first p-electrode and the second partial light-emitting part through the second p-electrode.

In the first aspect of the present invention, the pixel light-emitting parts are preferably arranged in a square lattice. The driving circuit preferably has a scanning line circuit sequentially selecting and scanning rows to be light emitted one by one of the subpixel light-emitting part, and a PWM circuit being formed at every column of the subpixel light-emitting part and controlling a current flowing to the subpixel light-emitting part according to a duty ratio for pulse width modulation.

Moreover, the driving circuit may turn ON the transistor in the row selected by the scanning line circuit, flow an output current of the PWM circuit to the subpixel light-emitting part, and make the subpixel emit a light. The driving circuit maintains the transistor in the row not selected by the scanning line circuit in OFF state, prevents the output current of the PWM circuit from flowing to the subpixel light-emitting part, and makes the subpixel not emit a light.

In the first aspect of the present invention, the subpixel light-emitting part may have a first subpixel light-emitting part, a second subpixel light-emitting part, and a third subpixel light-emitting part. The first subpixel light-emitting part preferably has a first light-emitting layer, and the second subpixel light-emitting part preferably has the first light-emitting layer and a second light-emitting layer. The third subpixel light-emitting part preferably has the first light-emitting layer, the second light-emitting layer, and a third light-emitting layer.

In the first aspect of the present invention, the light-emitting element may have an n-type semiconductor layer common to all subpixels, and an n-electrode being contacted with an exposed surface of the n-type semiconductor layer, the exposed surface surrounding the light-emitting element in a periphery area of the light-emitting element.

In a second aspect of the present invention, there is provided a LED display including a light-emitting element having a substrate, a semiconductor layer, an n-electrode, and a p-electrode, and a driving circuit substrate having the light-emitting element mounted thereon. The semiconductor layer has a first light-emitting part capable of emitting a light, and a second light-emitting part having a light emission failure. The first light-emitting part is electrically connected to the first p-electrode. The second light-emitting part is electrically connected to the second p-electrode. The driving circuit substrate has a driving circuit. The second p-electrode is not electrically connected to the driving circuit.

In a second aspect a height from a main surface of the driving circuit substrate to the second p-electrode may be larger than a height from the main surface of the driving circuit substrate to the first p-electrode. Accordingly, the second p-electrode cannot be electrically connected to the driving circuit.

In the second aspect of the present invention, the surface layer of the second p-electrode may be a metal oxide layer.

In a third aspect of the present invention, there is provided a method for producing a LED display, the method including inspecting a light-emitting part of a monolithic light-emitting element and mounting a light-emitting element to a driving circuit substrate. In mounting, a p-type semiconductor layer of the light-emitting part having a light emission failure is not electrically connected to an electrode of the driving circuit substrate.

In the third aspect of the present invention, additional steps may be carried out, for example, forming a base layer and a surface layer of an electrode being electrically connected to the light-emitting part, removing the surface layer to expose the base layer of the electrode being electrically connected to the light-emitting part having a light emission failure, and oxidizing the exposed base layer.

In exposing the base layer, a part of the base layer being electrically connected to the light-emitting part having a light emission failure may be removed.

Moreover, forming an electrode on the light-emitting part may be added. In inspecting the light-emitting part, a light emission image may be captured by making the light-emitting part of the light-emitting element emit a light by photoluminescence. The position of the light-emitting part having a light emission failure is specified from the light emission image. In forming the electrode, an electrode may be formed on the light-emitting part capable of emitting light without forming an electrode on the light-emitting part having a light emission failure.

In this LED display, one transistor TrR1 is provided for one subpixel light-emitting part R1. Two electrodes on the partial light-emitting part side are electrically connected to one electrode on the transistor side, thereby improving mountability of the light-emitting element.

In the method for producing the LED display according to the third aspect of the present invention, a short-circuited light-emitting part and a light-emitting part not emitting a light are not connected to the drive circuit. Since the light-emitting part having a light emission failure is not connected to the driving circuit, defective images are suppressed in the LED display produced by this method.

In the first aspect of the present invention, the driving circuit can be simplified while preventing defective images. Moreover, the LED display according to the second aspect of the present invention can be easily produced. In the LED display according to the third aspect of the present invention, defective images can be suppressed by a simple process.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the structure of a LED display DS according to a first embodiment;

FIG. 2 shows the deposition structure of the LED display DS according to the first embodiment;

FIG. 3 is a conceptual view showing the band structure and the behavior of electrons and holes in the LED display DS according to the first embodiment;

FIG. 4 is a circuit diagram schematically showing a driving circuit CC1 of the LED display DS according to the first embodiment;

FIG. 5 is a schematic view of the structure of a LED display DS according to a second embodiment;

FIG. 6 is a view drawn by extracting a p-electrode P1, a transparent substrate TS1, and a driving circuit substrate 200 from a micro-LED element 100 of the LED display DS according to the second embodiment;

FIG. 7 is a circuit diagram schematically showing a driving circuit CC1 of the LED display DS according to the second embodiment; and

FIGS. 8A to 8C are sketches showing processes for processing the p-electrode P1 of the micro-LED element 100 of the LED display DS according to the second embodiment.

### DETAILED DESCRIPTION OF PREFERRED EMBODIMENTS

A specific embodiment of the LED display will next be described with reference to the drawings. However, the present invention is not limited to the embodiments. The deposition structure of the layers and the electrode structure of the below-described LED display are given only for the illustration purpose, and other disposition structures differing therefrom may also be employed. The thickness ratio and aspect ratio of the layers shown in the drawings are not an actual value, but a conceptual value.

### First Embodiment

### 1. LED Display

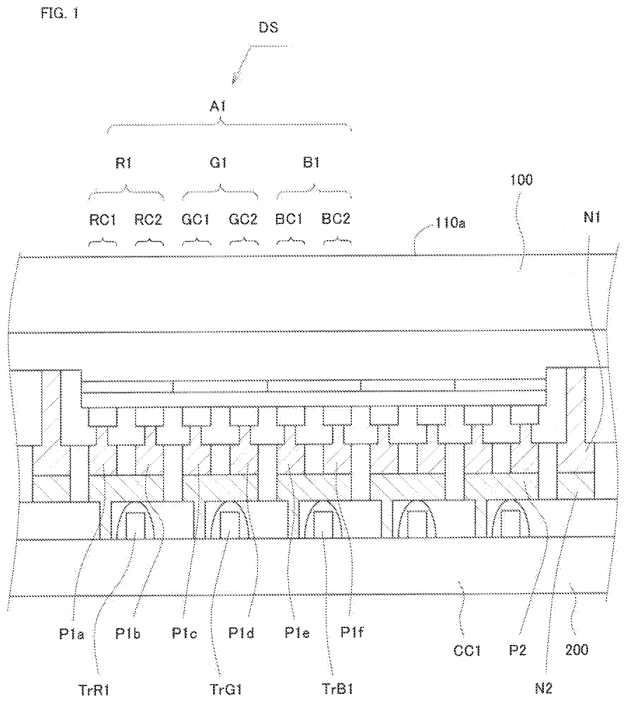

FIG. 1 is a schematic view of the structure of a LED display DS according to a first embodiment. The LED display DS includes a micro-LED element 100, and a driving circuit substrate (hereinafter referred to as “circuit substrate”) 200. As shown in FIG. 1, the micro-LED element 100 is a monolithic semiconductor light-emitting element having light-emitting elements integrated on the same substrate. Light is output upward from a main surface 110a of the substrate 110 in FIG. 1.

In the micro-LED element 100, A1 is one pixel light-emitting part (hereinafter referred to as “pixel”). The pixels are arranged in a square lattice. The pixel A1 has subpixel light-emitting parts (hereinafter referred to as “subpixel”) R1, G1, and B1. The subpixels R1, G1, and B1 are the regions emitting a red light, a green light, and a blue light, respectively.

The subpixel R1 emitting a red light has a first partial light-emitting part RC1 and a second partial light-emitting part RC2 connected in parallel with each other. Similarly, the subpixel G1 emitting a green light has a first partial light-emitting part GC1 and a second partial light-emitting part GC2 connected in parallel with each other. The subpixel B1 emitting a blue light has a first partial light-emitting part BC1 and a second partial light-emitting part BC2 connected in parallel with each other.

The first partial light-emitting part RC1 has a first p-electrode P1a. The second partial light-emitting part RC2 has a second p-electrode P1b. The first partial light-emitting part GC1 has a first p-electrode Plc. The second partial light-emitting part GC2 has a second p-electrode P1d. The first partial light-emitting part BC1 has a first p-electrode P1e. The second partial light-emitting part BC2 has a second p-electrode P1f. These p-electrodes can be shown as a p-electrode P1.

Each subpixel has a first partial light-emitting part and a second partial light-emitting part. The first partial light-emitting part and the second partial light-emitting part are adjacent, and electrodes are respectively connected to each subpixel. For example, if the first partial light-emitting part has a light emission failure, the second partial light-emitting part emits a light. Needless to say, each subpixel may have two or more partial light-emitting parts.

The circuit substrate 200 has a driving circuit CC1 for supplying a current to a micro-LED element 100.

### 2. Deposition Structure

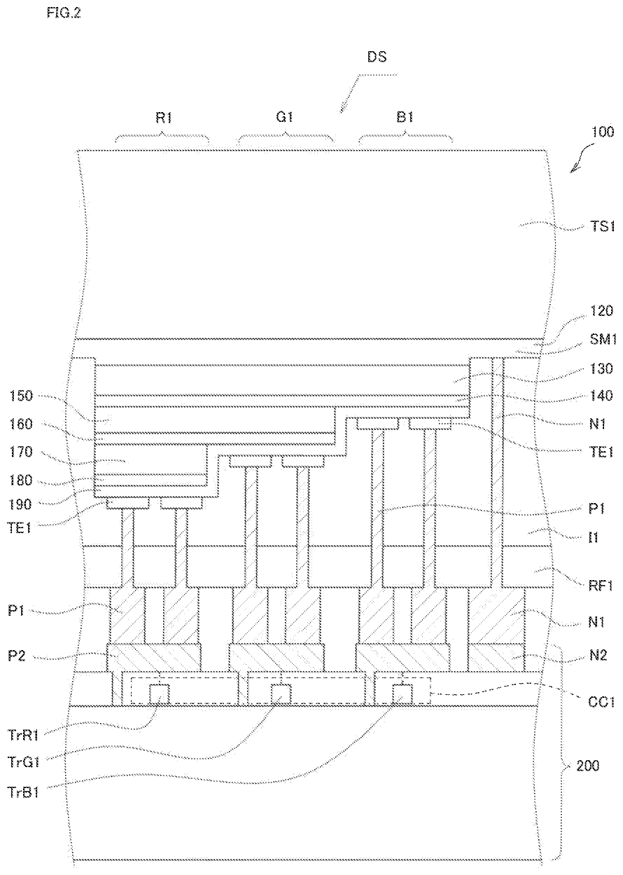

FIG. 2 shows the deposition structure of the LED display DS according to the first embodiment. As shown in FIG. 2, the micro-LED element 100 has a transparent substrate TS1, a semiconductor layer SM1, a p-electrode P1, an n-electrode N1, and a reflective layer RF1. The micro-LED element 100 is a monolithic Group III nitride semiconductor light-emitting element having a plurality of light-emitting parts arranged in a matrix in one element.

The transparent substrate TS1 is made of, for example, sapphire, GaN, and SiC.

The semiconductor layer SM1 has an n-type contact layer 120, a first light-emitting layer 130, a first intermediate layer 140, a second light-emitting layer 150, a second intermediate layer 160, a third light-emitting layer 70, a cap layer 180, and a p-type contact layer 190.

The circuit substrate 200 has a driving circuit CC1. The driving circuit CC1 has transistors TrR1, TrG1, and TrB1. The transistors TrR1, TrG1, and TrB1 are a selective transistor for selecting whether to make a current flow to the partial light-emitting parts.

The subpixel light-emitting part R1 has an n-type contact layer 120, a first light-emitting layer 130, a first intermediate layer 140, a second light-emitting layer 150, a second intermediate layer 160, a third light-emitting layer 170, a cap layer 180, and a p-type contact layer 190.

The subpixel light-emitting part G1 has an n-type contact layer 120, a first light-emitting layer 130, a first intermediate layer 140, a second light-emitting layer 150, a second intermediate layer 160, and a p-type contact layer 190.

The subpixel light-emitting part B1 has an n-type contact layer 120, a first light-emitting layer 130, a first intermediate layer 140, and a p-type contact layer 190.

Each p-electrode P1 is formed on its corresponding transparent electrode TE1. Each transparent electrode TE1 is separately formed on the p-type contact layer 190. The transparent electrodes TE1 and the p-electrodes P1 are arranged in a square lattice (matrix) pattern. As a result of this, the first partial light-emitting part and the second partial light-emitting part are respectively provided with the transparent electrode TE1 and the p-electrode P1. Moreover, the area surrounding each transparent electrode TE1 and each P-electrode P1 are insulated each other.

The n-electrode N1 is formed in a rectangular ring pattern along the periphery of the micro-LED element 100. A groove reaching the n-type contact layer 120 is formed by etching at the periphery of the micro-LED element 100, and the n-electrode N1 is formed on the n-type contact layer 120 exposed in the bottom of the groove. In one micro light-emitting element 100, only one n-electrode N1 is common to all subpixels. That is, the n-electrode N1 is common to all the first partial light-emitting parts and the second partial light-emitting parts. The n-electrode N1 is made of, for example, a layered material such as Ti/Al.

The micro-LED element 100 is not provided with a groove for separating pixels, and the n-electrode N1 is also common to the pixels. Therefore, micronization is possible.

The n-electrode pad N2 is formed on the circuit substrate 200 side. The n-electrode pad N2 is electrically bonded to the n-electrode N1 of the micro-LED element 100.

The p-electrode pad P2 is formed on the circuit substrate 200 side. The p-electrode pad P2 is electrically bonded to the p-electrode P1 of the micro-LED element 100.

An insulating layer 11 is a layer for insulating a plurality of p-electrodes P1. The insulating layer I1 insulates the transparent electrode TE1 of each partial light-emitting part.

### 3. Band Structure and Behavior of Electrons and Holes

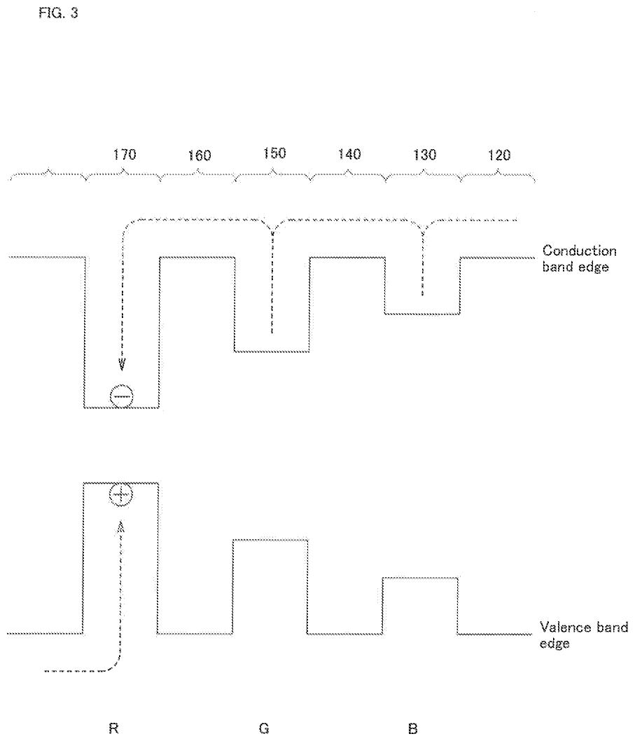

FIG. 3 is a conceptual view showing the band structure and the behavior of electrons and holes in the subpixel R1 in the LED display DS according to the first embodiment. In FIG. 3, for ease of explanation, each light-emitting layer is drawn as having a single quantum well structure. Each light-emitting layer may have a multi-quantum well structure.

Holes injected from the p-electrode P1 easily enter the third light-emitting layer 170. Most holes remain in the third light-emitting layer 170 without overflowing from the third light-emitting layer 170. This is because the barrier in the valence band of the second intermediate layer 160 is sufficiently high as viewed from the third light-emitting layer 170.

Electrons injected from the n-electrode N1 enter the first light-emitting layer 130. The barrier in the conduction band of the first intermediate layer 140 is not so high as viewed from the first light-emitting layer 130. Therefore, electrons easily move from the first light-emitting layer 130 to the second light-emitting layer 150. The barrier in the conduction band of the second intermediate layer 160 is not so high as viewed from the second light-emitting layer 150. Therefore, electrons easily move from the second light-emitting layer 150 to the third light-emitting layer 170. Most electrons entered the third light-emitting layer 170 remain in the third light-emitting layer 170 without overflowing. This is because the barrier in the conduction band of the cap layer 180 adjacent to the third light-emitting layer 170 is sufficiently high.

Thus, both electrons and holes easily exist in the third light-emitting layer 170. That is, electron wavefunction and hole wavefunction are overlapped each other while having a large amplitude at the third light-emitting layer 170. Thereby, the third light-emitting layer 170 intensively emits a red light, and the first light-emitting layer 130 and the second light-emitting layer 150 do not emit so much light.

When the third light-emitting layer 170 is not formed, the second light-emitting layer 150 intensively emits a light, and the first light-emitting layer 130 does not emit so much light.

### 4. Circuit. Substrate

### 4-1. Circuit Structure

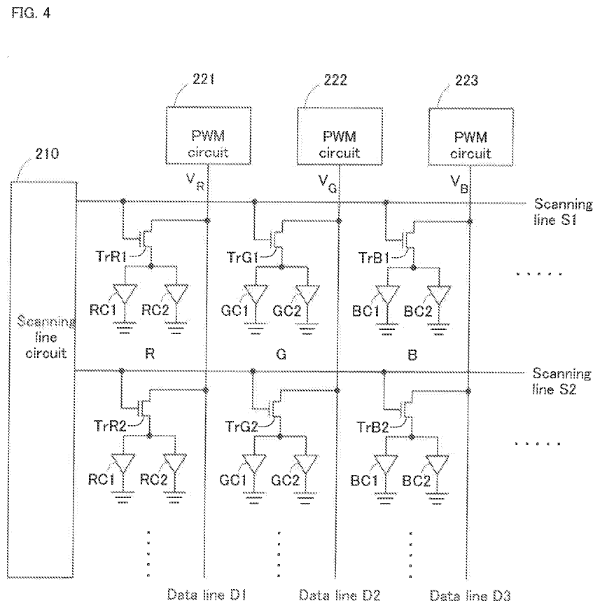

FIG. 4 is a circuit diagram schematically showing a driving circuit CC1 of the LED display DS according to the first embodiment. In FIG. 4, subpixels (R, G, and B) of the light-emitting element 100 are arranged in a square lattice pattern. In a first row of the lattice pattern, a group of diodes emitting red, green, and blue lights is one pixel. Similarly, in a second row of the lattice pattern, a group of diodes emitting red, green, and blue lights is one pixel. A plurality of these subpixels (R, G, and B) is arranged in row and column directions. As shown in FIG. 4, the driving circuit CC1 has a scanning line circuit 210, and PWM circuits 221, 222, 223, and so on. The driving circuit CC1 has scanning lines S1, S2, and so on, data lines D1, D2, D3, and so on, transistors TrR1, TrG1, TrB1, and so on in the first row, and transistors TrR2, TrG2, TrB2, and so on in the second row. The transistors (TrR1, TrG1, and TrB1) are a group of transistors for one pixel. The scanning line circuit 210 and the PWM circuits 221, 222, 223, and so on are achieved as an LSI element, and mounted on the circuit substrate 200.

The scanning line circuit 210 is a circuit for sequentially selecting the scanning lines S1, S2, and so on of the LED display DS, and applying a gate voltage to a gate of each transistor. A plurality of pixels (one pixel being a group of R, G, and B) is arranged in a row direction, and constitutes one pixel line. A plurality of these pixel lines is arranged in a column direction. The scanning line circuit 210 selects the pixel lines for displaying an image by selecting the scanning lines S1, S2, and so on. An image is displayed on the LED display by sequentially scanning these scanning lines in a column direction.

The PWM circuits 221, 222, 223, and so on are formed at every column of the LED display DS. The PWM circuits 221, 222, 223, and so on are respectively connected to the data lines D1, D2, D3, and so on. The PWM circuits 221, 222, 223, and so on are respectively the circuits for pulse width modulating a current flowing to the partial light-emitting parts (such as RC1 and RC2), (such as GC1 and GC2), and (such as BC1 and BC2). Brightness of each subpixel is controlled by a duty ratio. Brightness can be controlled by using PWM (Pulse Width Modulation), without causing a deviation in the emission wavelength of the subpixel. Thus, the PWM circuits 221, 222, 223, and so on are formed at every column of the subpixels R, G, and B, and control the duty ratio to pulse width modulate a current flowing to the subpixels R, G, and B. The PWM circuits have registers corresponding to the number of columns to store the brightness values of R, G, and B, and the value of each register is changed in synchronization with the selection of the scanning line. A PWM signal controlled by the duty ratio according to the value of each register is output to each data line.

The scanning line is formed at every row of the LED display DS. The scanning line S1 is connected in parallel with gates of the transistors TrR1, TrG1, and TrB1 in its corresponding row.

The data line is formed at every column of the LED display DS. The data line D1 is connected to drain electrodes of the transistors TrR1, TrR2, and so on for emitting a red light in the first column. The data line D2 is connected to drain electrodes of the transistors TrG1, TrG2, and so on for emitting a green light in the second column. The data line D3 is connected to drain electrodes of the transistors TrB1, TrB2, and so on for emitting a blue light in the third column.

The transistors such as TrR1, TrG1, and TrB1 are formed for every subpixel. Source electrodes of the transistors TrR1, TrG1, and TrB1 are connected to an anode (p-electrode P1) of the partial light-emitting part (such as RC1). ON/OFF of the transistors TrR1, TrG1, and TrB1 is controlled by applying a voltage to a gate. In the ON state, a current can flow to the partial light-emitting part (such as RC1), and in the OFF state, a current does not flow to the partial light-emitting part (such as RC1).

The subpixel R has a first partial light-emitting part RC1, a second partial light-emitting part RC2, and a transistor TrR1. The subpixel G has a first partial light-emitting part GC1, a second partial light-emitting part GC2, and a transistor TrG1. The subpixel B has a first partial light-emitting part BC1, a second partial light-emitting part BC2, and a transistor TrB1.

The transistors TrR1, TrG1, and TrB1 in the row selected by the scanning line circuit 210 are turned ON so that a current can flow to the subpixel light-emitting parts R1, G1, and B1. The transistors in the row not selected by the scanning line circuit 210 maintain OFF state so that a current does not flow to the subpixels R, G, and B.

### 4-2. Arrangement of Transistors

The driving circuit CC1 has one transistor for one subpixel. The transistor TrR1 is electrically connected to the first partial light-emitting part. RC1 through a p-electrode P1a and the second partial light-emitting part RC2 through a p-electrode P1b. Other transistors TrG1 and TrB1 are connected in the same way.

As shown in FIG. 1, a p-electrode pad P2 and a common n-electrode pad N2 are formed for each subpixel on the circuit substrate 200. Source electrodes of the transistors TrR1, TrG1, and TrB1 are connected to the p-electrode pad P2. Two electrodes, the p-electrode p1a of the first partial light-emitting part RC1 (LED) and the p-electrode p1b of the second partial light-emitting part RC2 (LED), are connected to one p-electrode pad P2. Therefore, the micro-LED element 100 is easily mounted to the circuit substrate 200. That is, even if the position accuracy is not so high, bonding failure hardly occurs.

### 4-3. Operation of Circuit

Firstly, the scanning line circuit 210 selects one of the scanning lines S1, S2, and so on. At this time, a voltage is applied to the gates of the transistors connected to the selected scanning line S1, S2, and so on. At this stage, the partial light-emitting part connected to the source electrode of the transistor does not emit a light.

When the scanning line circuit 210 is selected, the voltages V_{R}, V_{G}, V_{B} and so on pulse width-modulated according to the brightness of R, G, and B is generated at the data lines D1, D2, D3, and so on of the PWM circuit 221, 222, and so on. This voltage is applied to the drain electrode of the transistor. Thus, a current in the amount according to the PWM voltage flows to two partial light-emitting parts connected to the source electrode of the transistor, and these partial light-emitting parts emit a light with the commanded brightness.

### 5. Effect of First Embodiment

In the LED display DS according to the first embodiment, the subpixel R has a first partial light-emitting part RC1 and a second partial light-emitting part RC2. One transistor TrR1 is formed for one subpixel R. One transistor TrR1 supplies a current to the first partial light-emitting part RC1 and the second partial light-emitting part RC2. The first partial light-emitting part RC1 and the second partial light-emitting part RC2 are connected in parallel. Therefore, even if one of the first partial light-emitting part RC1 and the second partial light-emitting part RC2 has a light emission failure, the other partial light-emitting part emits a light. Especially, when open conduction failure occurs in one partial light-emitting part or a current line is disconnected, a double current is supplied to the other partial light-emitting part so that the brightness of that subpixel is maintained to a command value. Thus, a defective image hardly occurs in the LED display DS.

As mentioned above, one transistor TrR1 is provided for one subpixel R. Thereby, the driving circuit CC1 can be simplified, and the LED display DS can be miniaturized. Moreover, the PWM circuits 221, 222, 223 and so on are formed at every column. The number of circuits can be decreased compared to when the PWM circuit 221, 222, 223 and so on are formed for every partial light-emitting part. That is, the LED display DS can be micronized. Thus, the driving circuit. CC1 is simplified, thereby suppressing the occurrence of defective parts due to defective bonding, that is, improving the yield.

### 6. Variations

### 6-1. Number of Driving Circuits

The LED display DS according to the first embodiment has one driving circuit CC1. However, the LED display 1 may be divided into a plurality of regions, and the driving circuit CC1 may be provided for each region.

### Second Embodiment

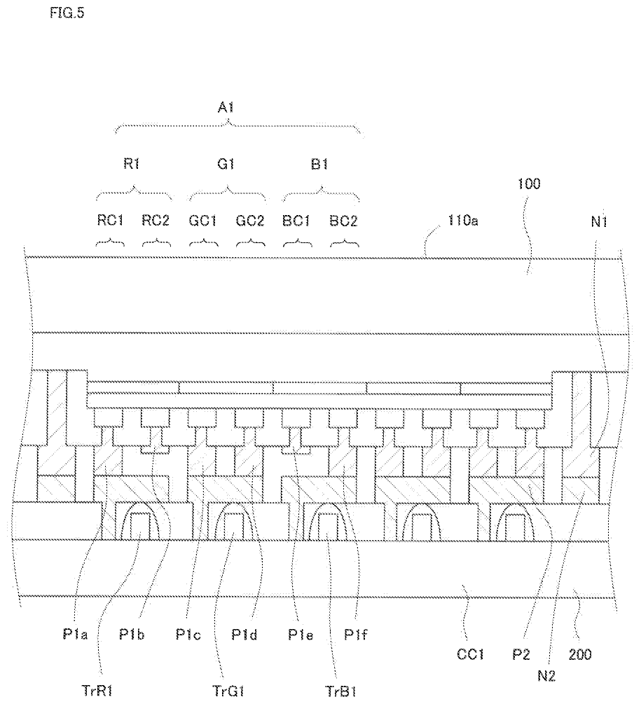

The LED display DS according to a second embodiment has the same structure as the structure of the LED display DS according to the first embodiment shown in FIG. 1 except for the connecting structure of the p-electrode and the p-electrode pad. The LED display DS has the structure shown in FIG. 5.

### 1. Electrode Structure

As shown in FIG. 5, in the LED display DS according to the second embodiment, an electrode connected to a partial light-emitting part having a light emission failure is not electrically connected to a driving circuit CC1.

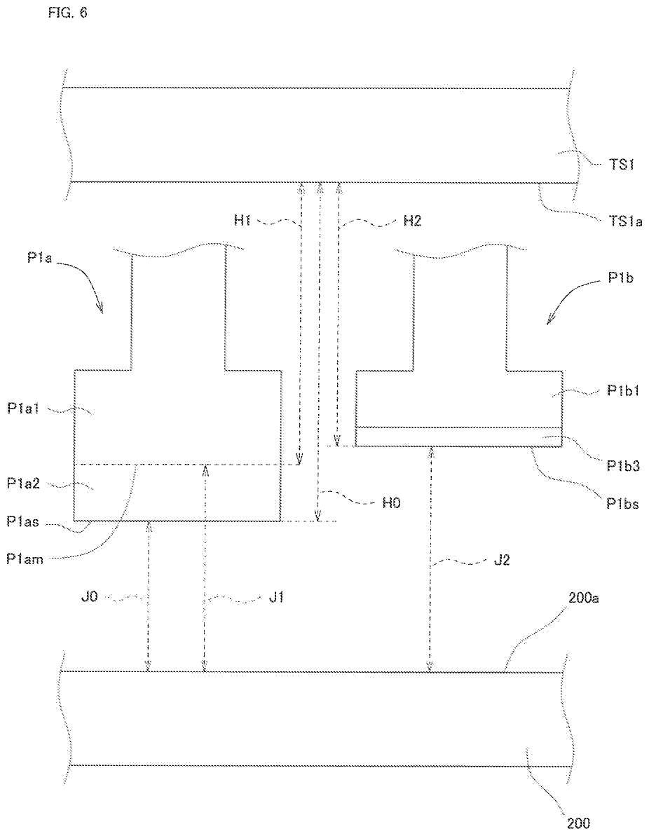

FIG. 6 is a view drawn by extracting a p-electrode P1, a transparent substrate TS3, and a circuit substrate 200 from a micro-LED element 100 of the LED display DS according to the second embodiment.

For ease of explanation, as shown in FIG. 5, when the first partial light-emitting parts RC1, GC1, GC2, and BC2 are a light-emitting part capable of excellently emitting a light (first light-emitting part), and the second partial light-emitting parts RC2 and BC1 are a light-emitting part having a light emission failure (second light-emitting part). In FIG. 5, the second light-emitting part is a light-emitting part not connected to a p-electrode pad P2. For example, the brightness of the light-emitting part having a light emission failure is lower by 20% or more compared to the brightness of the light-emitting part capable of excellently emitting a light. As described later, light emission failures in the second partial light-emitting parts RC2 and BC1 are detected by the inspection process.

A normal first partial light-emitting part RC1 (hereinafter referred to as “normal part”) and a defective second partial light-emitting part RC2 (hereinafter referred to as “defective part”) are described as an example. As shown in FIG. 6, the p-electrode P1a of the normal part has a base layer P1a1 and a surface layer P1a2. The p-electrode P1b of the defective part has a base layer P1b1 and a surface layer P1b3. The base layer P1a1 of the normal part is made of the conductive material same as the material of the base layer P1b1 of the defective part. For example, Ti, Al, Ni, and Cr are used. A metal or alloy other than the above may be used. These materials are a metal relatively easy to be oxidized.

The material of the surface layer P1a2 of the p-electrode P1a of the normal part is different from the material of the surface layer P1b3 of the p-electrode P1b of the defective part. The material of the surface layer P1b3 of the p-electrode P1b of the defective part is an oxide of the material of the base layer P1b1, that is, a metal oxide. The surface layer P1b3 is made of an insulating material, for example, TiO₂, Al₂O₃, NiO, and Cr₂O₃.

The p-electrode P1a of the normal part is connected to the p-electrode pad P2 on the circuit substrate 200. That is, the p-electrode P1a is electrically connected to the driving circuit CC1. The base layer P1a1 and the surface layer P1a2 are made of a conductive material. The surface layer P1a2 is made of a metal or alloy, for example, Ti, Al, Ag, and Au.

The p-electrode P1b of the defective part is not connected to the p-electrode pad P2 on the circuit substrate 200. That is, the p-electrode P1b is not electrically connected to the driving circuit CC1.

### 1-1. Positional Relationship of Electrode Surfaces

As shown in FIG. 6, a height from a main surface TS1a of the transparent substrate TS1 to a surface P1as of the p-electrode P1a of the normal part is defined as H0. A height from the main surface TS1a of the transparent substrate TS1 to a surface P1bs of the p-electrode P1b of the defective part is defined as H2. The height H0 is larger than the height H2. Here, the surfaces P1as and P1bs are the surfaces facing each other closest to a main surface 200a of the circuit substrate 200.

A height from the main surface TS1a of the transparent substrate TS1 to an interface P1am between the base layer P1a1 and the surface layer P1a2 of the p-electrode P1a of the normal part is defined as H1. A height from the main surface TS1a of the transparent substrate TS1 to the surface P1bs of the p-electrode P1b is defined as H2. The height H1 is larger than the height H2.

A height from the main surface 200a of the circuit substrate 200 to the surface P1bs of the p-electrode P1b of the defective part is defined as J2. A height from the main surface 200a of the circuit substrate 200 to the surface P1as of the p-electrode P1a of the normal part is defined as J0. The height J2 is larger than the height J0.

A height from the main surface 200a of the circuit substrate 200 to the interface P1am between the base layer P1a1 and the surface layer P1a2 of the p-electrode P1a of the normal part is defined as J1. A height from the main surface 200a of the circuit substrate 200 to the surface P1bs of the p-electrode P1b of the defective part is defined as J2. The height J1 is smaller than the height J2.

The p-electrode P1a of the normal part and the p-electrode P1b of the defective part have such a positional relationship to the main surface 200a of the circuit substrate 200. Moreover, the surface layer P1b3 of the p-electrode P1b of the defective part is made of an insulating material. Therefore, the p-electrode P1b of the defective part is not electrically connected to the driving circuit CC1 of the circuit substrate 200.

The surface P1as of the p-electrode P1a of the normal part is bonded to the p-electrode pad P2 of the circuit substrate 200 through a bonding layer such as solder. Thus, the position of the surface P1as of the p-electrode P1a can be specified.

On the other hand, the surface P1bs of the p-electrode P1b of the defective part is not bonded to a bonding layer such as solder, and faces a gas layer such as air. As shown in FIG. 6, this is because there is a height difference from the surface P1as of the p-electrode P1a and the surface P1bs of the p-electrode P1b to the main surface 200a of the circuit substrate 200.

### 2. Circuit Structure

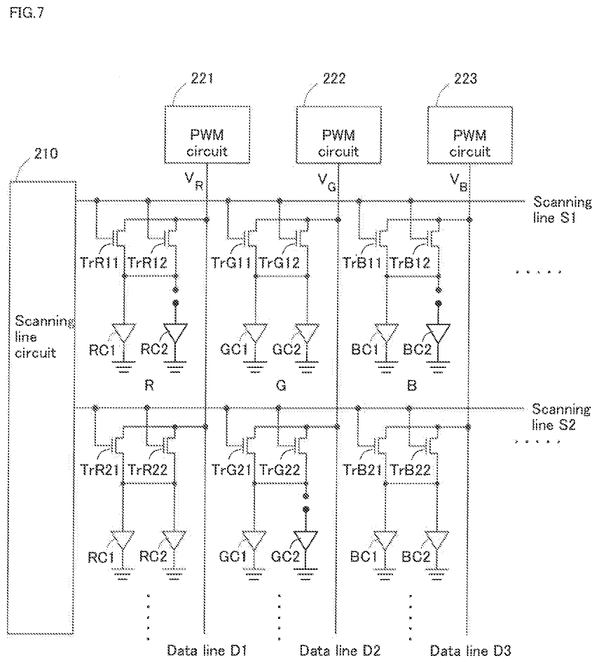

The driving circuit of the second embodiment is the same as the driving circuit (FIG. 4) of the first embodiment in the point that the elements are arranged in a lattice. Only the circuit structure of one subpixel is different. In the circuit diagram of FIG. 7, the subpixels R and B in the first row has a defective partial light-emitting part. The subpixel G in the second row has a defective partial light-emitting part.

The subpixel R emitting a red light is described below. As shown in FIG. 7, the subpixel R has a partial light-emitting part RC1, a partial light-emitting part RC2, a transistor TrR11, and a transistor TrR12. Two columns of the light-emitting diodes and two columns of transistors are parallel-connected.

A voltage V_{R} output from the PWM circuit 221 is applied to the drain electrodes of the transistors TrR11 and TrR12. A gate voltage is applied from the scanning line S1 to the gate electrodes of the transistors TrR11 and TrR12 so that the transistors TrR11 and TrR12 are ON-OFF controlled.

Here the transistor TrR12 is not electrically connected to the second partial light-emitting part RC2 having a light emission failure, for example, short-circuit failure. A current path to the second partial light-emitting part RC2 is open. That is, the source electrode of the transistor TrR12 is not connected to the anode electrode (p-electrode P1b in FIG. 5) of the second partial light-emitting part RC2. Thus, the transistor TrR12 cannot supply a current to the second partial light-emitting part RC2 regardless of the operation of the scanning line circuit 210.

The scanning of subpixels, i.e., applying a gate voltage and the application of a drain voltage to a data line are the same as described in the circuit diagram shown in FIG. 4 of the first embodiment. The difference from the first embodiment is that a current does not always flow to the second partial light-emitting part RC2 because the p-electrode P1b of the second partial light-emitting part RC2 having a light emission failure is not electrically connected. However, the first partial light-emitting part RC1 with a normal light emission is supplied with a current through the p-electrode pad P2 from the transistor TrR12. Accordingly, the first normal partial light-emitting part RC1 is supplied with a double amount of a normal current so that the emission strength does not decrease as a whole subpixel R.

In this case, the p-electrode pad P2 is common with respect to the first and second partial light-emitting parts RC1 and RC2. However, the p-electrode pad P2 may be separated with two parts corresponding to each of the first and second partial light-emitting parts RC1 and RC2 though the emission strength of the subpixel R decreases.

### 3. Method for Producing LED Display

Next will be described the method for producing a micro-LED element 100. In FIG. 2, a semiconductor layer SM1 is sequentially formed on a transparent substrate TS1. On the semiconductor layer SM1, transparent electrodes TE1 are separately formed in a square lattice for each of two light-emitting parts of subpixel. Similarly, on the transparent electrodes TE1, p-electrodes P1 are separately formed for each of two light-emitting parts of subpixel. That is, the transparent electrodes and the p-electrodes are separately formed twice as many as the subpixels. In this way, a base layer and a surface layer of the p-electrode P1 being electrically connected to the light-emitting part are formed. A recess reaching from the p-type contact layer 190 to the n-type contact layer 120 is formed and an n-electrode N1 is formed in the recess.

### 3-1. Inspection Process

The light-emitting part of the micro-LED element 100 is inspected. The existence of the partial light-emitting part having a light emission failure is inspected by supplying a current to each light-emitting part. Thereby, the position of the partial light-emitting part having a light emission failure is specified. Through the inspection, it is detected, for example, that the second partial light-emitting part RC2 has a light emission failure.

### 3-2. Exposing Base Layer

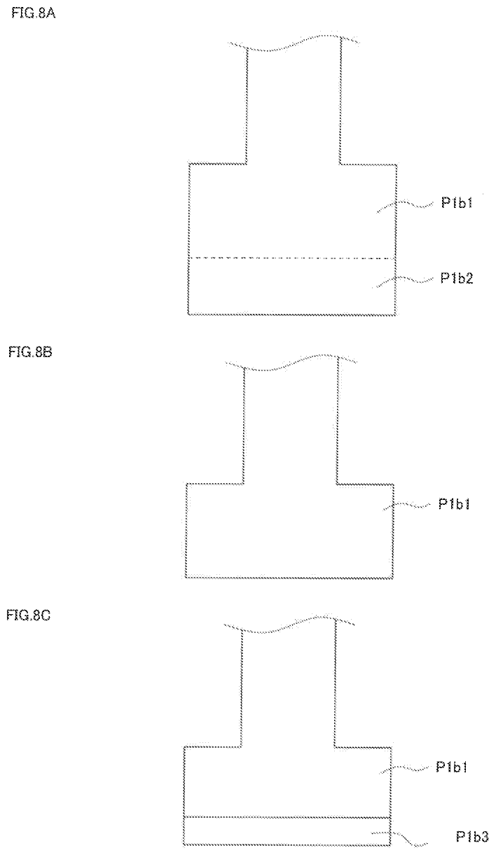

FIGS. 8A to 8C are sketches showing processes for processing a p-electrode P1 of the micro-LED element 100 of the LED display DS according to the second embodiment.

The surface layer P1b2 of the p-electrode P1b of the second partial light-emitting part RC2 of the defective part is trimmed by laser trimming up to a middle of the base layer P1b1. Thereby, the base layer P1b1 of the p-electrode P1b is exposed. In this way, in exposing the base layer, the surface layer P1b2 being electrically connected to the light-emitting part having a light emission failure is removed, and a part of the base layer P1b1 being electrically connected to the light-emitting part having a light emission failure is removed.

### 3-3. Oxidizing Base Layer

Subsequently, the surface of the exposed base layer P1b1 is oxidized. A region other than the exposed base layer P1b1 is masked so that only the base layer P1b1 is oxidized. Thereby, the surface of the base layer P1b1 is oxidized, and the surface layer P1b3 is formed. The surface layer P1b3 is an oxide layer formed by oxidizing the base layer P1b1.

### 3-4. Mounting Process

The micro-LED element 100 is mounted on the circuit substrate 200. In this mounting process, the p-type semiconductor layer of the light-emitting part capable of emitting a light is electrically connected to the electrode pad P2 of the circuit substrate 200, and the p-type semiconductor layer of the light-emitting part having a light emission failure is not electrically connected to the electrode pad P2 of the circuit substrate 200. The micro-LED element 100 is bonded to the circuit substrate 200 by reflowing solder and others. Or other bonding method may be used.

### 4. Effect of Second Embodiment

In the method for producing the LED display DS according to the second embodiment, the partial light-emitting part having a light emission failure is not electrically connected to the driving circuit CC1. For that purpose, the surface layer of the p-electrode P1 formed on the partial light-emitting part having a light emission failure is removed to expose the base layer, and such exposed base layer is oxidized. This oxide layer has insulating properties.

The height J2 from the main surface 200a of the circuit substrate 200 to the p-electrode P1b of the second partial light-emitting part RC2 is larger than the height J0 from the main surface 200a of the circuit substrate 200 to the p-electrode P1a of the first partial light-emitting part RC1. Therefore, when the micro-LED element 100 is mounted, the p-electrode P1b of the second partial light-emitting part RC2 is not solder bonded. Accordingly, the p-electrode P1b is not electrically connected to the driving circuit CC1.

Thus, an air layer and an oxide layer (surface layer P1b3) exist between the p-electrode P1b of the second partial light-emitting part RC2 and the electrode pad P2 of the circuit substrate 200. Therefore, the partial light-emitting part having a light emission failure (such as RC2) is not electrically connected to the driving circuit CM1.

The PWM circuits 221, 222, 223, and so on are formed at every column. Thereby, the number of circuits can be decreased compared to when the PWM circuit 221, 222, 223 and so on are formed for every partial light-emitting part. That is, the LED display DS can be micronized. Although a part of the electrode is trimmed, there is no risk of damaging the semiconductor layer. The micro-LED element 100 may be purchased. From the above, the micro-LED element 100 is prepared.

### Third Embodiment

Next will be described a third embodiment.

The micro-LED element according to the third embodiment has the same structure as that of the micro-LE) element 100 according to the second embodiment except that the electrode itself of the light-emitting part having a light emission failure is removed. This micro-LED element is not provided with an electrode on the light-emitting part having a light emission failure.

Similarly as in the second embodiment, a semiconductor layer SM1 is sequentially formed on the transparent substrate TS1. In the inspection process, the light-emitting part of the semiconductor layer is inspected by photoluminescence. A light emission image is captured by a camera and other devices, by making the light-emitting part of the micro-LED element according to the third embodiment emit a light. Then, the light emitting region and the non-light emitting region are specified from the captured light emission image. Thereby, the position of the partial light-emitting part having a light emission failure is specified.

An electrode is formed on the light-emitting parts specified as the light emitting region. An electrode is formed only on the light-emitting part capable of excellently emitting a light, without forming an electrode on the light-emitting part having a light emission failure. For example, a mask is formed on the light-emitting part having a light emission failure, and an electrode is formed on the light-emitting part other than the masked light-emitting part. After that, the mask is removed from the light-emitting part having a light emission failure. In this way, the micro-LED element is produced. After that, the micro-LED element is mounted on the circuit substrate 200. Thus, the LED display according to the third embodiment is produced.

In the method for producing the LED display according to the third embodiment, the light-emitting part having a light emission failure can be specified before forming an electrode. Therefore, the electrode needs not to be removed, and the semiconductor layer is hardly damaged.

What is claimed is:

1. A LED display comprising a monolithic light-emitting element having a plurality of light-emitting parts formed on a substrate, and a driving circuit substrate having a driving circuit for supplying a current to the light-emitting element formed thereon, wherein,
the light-emitting element has a pixel light-emitting part corresponding to one pixel,
the pixel light-emitting part has not less than one subpixel light-emitting part,
the subpixel light-emitting part has a first partial light-emitting part and a second partial light-emitting part connected in parallel, the first partial light-emitting part having a first p-electrode, and the second partial light-emitting part having a second p-electrode,
the driving circuit has one transistor for the one subpixel light-emitting part, and
one terminal of the transistor is electrically connected to the first partial light-emitting part through the first p-electrode and the second partial light-emitting part through the second p-electrode.

2. The LED display according to claim 1, wherein the pixel light-emitting parts are arranged in a square lattice,
the driving circuit has a scanning line circuit sequentially selecting and scanning rows to be light emitted one by one of the subpixel light-emitting part, and a PWM circuit being formed at every column of the subpixel light-emitting part and controlling a current flowing to the subpixel light-emitting part according to a duty ratio for pulse width modulation.

3. The LED display according to claim 2, wherein the driving circuit turns ON the transistor in the row selected by the scanning line circuit, flows an output current of the PWM circuit to the subpixel light-emitting part, and makes the subpixel emit a light, and
the driving circuit maintains the transistor in the row not selected by the scanning line circuit in OFF state, prevents the output current of the PWM circuit from flowing to the subpixel light-emitting part, and makes the subpixel not emit a light.

4. The LED display according to claim 1, the subpixel light-emitting part has a first subpixel light-emitting part, a second subpixel light-emitting part, and a third subpixel light-emitting part, wherein
the first subpixel light-emitting part has a first light-emitting layer,
the second subpixel light-emitting part has the first light-emitting layer and a second light-emitting layer, and
the third subpixel light-emitting part has the first light-emitting layer, the second light-emitting layer, and a third light-emitting layer.

5. The LED display according to claim 1, wherein the light-emitting element has an n-type semiconductor layer common to all subpixels, and an n-electrode being contacted with an exposed surface of the n-type semiconductor layer, the exposed surface surrounding the light-emitting element in a periphery area of the light-emitting element.

6. A LED display comprising a light-emitting element having a substrate, a semiconductor layer, an n-electrode, and a p-electrode, and a driving circuit substrate having the light-emitting element mounted thereon, wherein
the semiconductor layer has a first light-emitting part capable of emitting a light, and a second light-emitting part having a light emission failure, the first light-emitting part being electrically connected to the first p-electrode, and the second light-emitting part being electrically connected to the second p-electrode,
the driving circuit substrate has a driving circuit,
the second p-electrode is not electrically connected to the driving circuit.

7. The LED display according to claim 6, wherein a height from a main surface of the driving circuit substrate to the second p-electrode is larger than a height from the main surface of the driving circuit substrate to the first p-electrode.

8. A LED display according to claim 6, wherein the surface layer of the second p-electrode is a metal oxide layer.

9. A method for producing a LED display, the method comprising:
inspecting a light-emitting part of a monolithic light-emitting element; and
mounting a light-emitting element to a driving circuit substrate, wherein
a p-type semiconductor layer of the light-emitting part having a light emission failure is not electrically connected to an electrode of the driving circuit substrate.

10. The method for producing the LED display according to claim 9, the method comprising:
forming a base layer and a surface layer of an electrode being electrically connected to the light-emitting part;
removing the surface layer to expose the base layer of the electrode being electrically connected to the light-emitting part having a light emission failure; and
oxidizing the exposed base layer.

11. The method for producing the LED display according to claim 10, wherein in exposing the base layer, a part of the base layer being electrically connected to the light-emitting part having a light emission failure is removed.

12. The method for producing the LED display according to claim 9, the method comprising:
forming an electrode on the light-emitting part, wherein
in inspecting the light-emitting part, a light emission image is captured by making the light-emitting part of the light-emitting element emit a light by photoluminescence, and the position of the light-emitting part having a light emission failure is specified from the light emission image.
in forming the electrode, an electrode is formed on the light-emitting part capable of emitting a light without forming an electrode on the light-emitting part having a light emission failure.
